(19) United States
(12) Patent Application Publication
(10) Pub. No.: US 2004/0084150 A1
(43) Pub. Date: May 6, 2004

(54) Photoresist implant crust removal

(76) Inventors: Rene George, San Jose, CA (US); John Zajac, San Jose, CA (US); Daniel J. Devine, Los Gatos, CA (US); Craig Ranft, Fremont, CA (US); Andreas Kadavanich, Fremont, CA (US)

Correspondence Address: BOULDER PATENT SERVICE INC, 1021 GAPTER ROAD, BOULDER, CO, 803032924

(21) Appl. No.: 10/665,267

(22) Filed: Sep. 17, 2003

Related U.S. Application Data
(60) Provisional application No. 60/412,067, filed on Sep. 18, 2002.

(51) Int. Cl. H01L 21/306

(52) U.S. Cl. 156/345.39

(57) ABSTRACT

A process material crust, such an ion-implanted photoresist, is removed from a treatment object. A halogen-free plasma is generated using a hydrocarbon gas in combination with oxygen gas to subject the crust to the plasma. Methane may be used as the hydrocarbon gas. This plasma may also be use to remove underlying unaltered photoresist and ion implantation related residues. The plasma may likewise be generated using a hydrogen containing gas, which may be pure hydrogen gas, in combination with oxygen gas. Several techniques are used which employ exposure of the treatment to a hydrogen/oxygen based plasma with subsequent exposure to a hydrocarbon/oxygen based plasma.

### RELATED APPLICATION

The present application claims priority from U.S. Provisional Patent Application Serial No. 60/412,067, filed on Sep. 18, 2002, entitled PHOTORESIST IMPLANT CRUST REMOVAL which is incorporated herein by reference in its entirety.

### BACKGROUND OF THE INVENTION

The present invention relates generally to device processing including semiconductor and flat panel display device processing and, more particularly, to a system and method for removal of at least an ion implanted photoresist layer.

During device manufacturing, various materials are deposited onto a substrate, generally a silicon wafer or a flat glass substrate, to convert some portion of the surface of the substrate into a functional integrated circuit device. For instance, a bare silicon wafer may be masked with materials such as silica (monoxide or dioxide), silicon nitride, and photoresist to protect areas on the wafer during different process steps. Subsequent to certain processing steps, materials must be removed from the surface of the wafer. These materials may include photoresist layers which have been subjected to high dose ion implantation which drives the implanted species into the photoresist. Such ion implanted photoresist exhibits characteristics that are quite different from the original photo resist. It has been theorized that these species modify the photoresist as they provide energies sufficient to drive out hydrogen from the photoresist, thus altering its chemistry and bonding structure throughout the thickness of the penetration depth. Analysis of this altered layer has shown that this layer has high levels of cross linking as well as double- and triple-bonded carbon atoms. This modified surface layer of the photoresist is often referred to as the implant crust or simply crust.

The prior art has developed a number of processes in an attempt to remove the hardened crust using dry plasma processing. The more successful of these techniques share a particular feature by using halogens in the plasma. As an example, carbon tetrafluoride, CF₄, is often used. While some of these prior art techniques suggest that other components in the plasma, such as hydrogen at low concentration, are effective or assist in removal of the implanted crust, it is submitted that the halogen is the responsible agent. Unfortunately, however, the halogen species in the plasma are not selective to the photoresist and may damage the active devices and structures on the wafer.

One approach, which does not use a halogen with hydrogen, is described in U.S. Pat. No. 4,861,424 (hereinafter the '424 patent). The patent, however, teaches directly away from the use of oxygen in the plasma since it asserts that problematic, nonvolatile oxides (for example, phosphorous pentaoxide) are formed in the presence of oxygen, as described, for example, at column 1, lines 50-57. Consistent with this teaching against oxygen use for purposes of implant crust removal, the '424 patent teaches instead the use of nitrogen in combination with hydrogen (see, for example, column 2, lines 38-39). It is of further interest to note that a low hydrogen content of only 3% is used with 97% nitrogen, as described at column 4, lines 25-26. For reasons that will be brought to light below, the approach of the '424 patent is considered to be diametrically opposed to the approach of the present invention.

Another prior art approach, which uses a hydrogen containing plasma, is seen in U.S. Pat. No. 5,628,871 (hereinafter the '871 patent). Like the '424 patent, this reference uses an oxygen free plasma in order to avoid formation of the aforementioned nonvolatile oxides during implant crust removal (see column 1, lines 57-64). Further, a separate step is employed with oxygen only after removal of the implant crust for purposes of bulk, underlying photoresist removal (see, for example, column 2, lines 29-40). Accordingly, the '871 uses an approach that is consistent with that taken by the '424 patent and directly opposed to the approach taken by the present invention with respect to implant crust removal, as will be further described below.

Moreover, the prior art also contains examples of removing residues which may remain after the implanted photoresist crust and underlying photoresist has been removed. As will be further described below, residues can consist of any or all of remnants of sputtered silicon or silicon dioxide (or whatever material the substrate is formed from), carbonized materials and the implanted species. It should be appreciated that there can be more than one implanted species present at the same time. In this regard, the '424 patent takes the approach of using a wet, nitric acid exposure or an oxygen plasma. The latter is used only after the implant crust has been removed (see, for example, column 4, lines 41-48). The '871 patent bears a striking similarity to the approach of the '424 patent with respect to residue removal.

The present invention provides a system and method which does not use halogens while providing still further ages, as will be described below.

### SUMMARY OF THE INVENTION

As will be discussed in more detail hereinafter, there is disclosed herein a plasma reactor system having a treatment chamber containing a treatment object and method at least for use in removing a process material crust from the treatment object. In one aspect of the present invention, a plasma, which is free of halogens, at least to an approximation, is generated in the treatment chamber using a hydrocarbon gas in combination with oxygen gas in a way which subjects the process material to the plasma for use in removal of at least the process material crust. In one feature, methane is used as the hydrocarbon gas. In another feature, the process material is a photoresist and the process material crust is formed by ion implantation of an original photoresist layer on a surface of the treatment object. In still another feature, the hydrocarbon/oxygen plasma is used to remove at least one of an unaltered portion of the photoresist layer and an ion implantation related residue.

In another aspect of the present invention, a plasma is generated in the treatment chamber, which is free of halogens, at least to an approximation, using a hydrogen containing gas in combination with oxygen gas such that an overall gas mixture includes at least 15% hydrogen in a way which subjects the process material crust to the plasma for use in removal of the process material crust. In one feature, the hydrogen containing gas consists essentially of hydrogen gas. In another feature, the hydrogen gas is provided in the overall gas mixture in a range from approximately 15% to 85%. In still another feature, each of hydrogen gas and the oxygen gas make up at least approximately one-half of the overall gas mixture. In still another feature, a hydrogen/oxygen plasma is used to remove at least one of an unaltered portion of the photoresist layer and an ion implantation related residue

In still another aspect of the present invention, an at least generally halogen free plasma is generated using a gas in combination with oxygen gas in a way which produces at least one of CH₂ radicals and CH₃ radicals in the plasma to subject the process material crust to the plasma for use in removal of the process material crust.

In a continuing aspect of the present invention, a plasma reactor system and method are provided for use in removing a photoresist layer from a treatment object. The photoresist layer includes an outermost crust formed by exposure of the photoresist to an ion implantation source. The treatment object is supported in a treatment chamber. A first least generally halogen free plasma is generated using hydrogen gas in combination with oxygen gas in a way which subjects the outermost crust of the treatment object in the treatment chamber to the first plasma to remove at least a substantial portion of the outermost crust so as to leave an innermost portion of the photoresist layer on the treatment object. At least a substantial part of the innermost portion of the photoresist layer is then removed such that a residue remains on the treatment object. The residue relating to at least one of the outermost crust and the innermost portion of the photoresist layer. A second at least generally halogen free plasma is generated using a hydrocarbon gas in combination with oxygen gas. The treatment object is exposed to the second plasma to remove the residue from the treatment object.

In a further aspect of the present invention, a plasma reactor system is used at least for removing a photoresist layer from a treatment object. The photoresist layer includes an outermost crust formed by exposure of the photoresist to an ion implantation source in a way which may additionally form residues. The treatment object is supported in a treatment chamber. A first plasma is produced using hydrogen gas in combination with oxygen gas such that the first plasma is substantially free of halogens and in a way which subjects at least the outermost crust to the first plasma to remove at least a portion of the outermost crust so as to leave an underlying portion of the photoresist layer on the treatment object along with at least a portion of the residues. Thereafter, a second plasma is generated using a hydrocarbon gas in combination with oxygen gas such that the second plasma is substantially free of halogens and the underlying portion of the photoresist layer and any remaining portion of the implant residues are exposed to the second plasma for removal from the treatment object.

In yet another aspect of the present invention, a plasma reactor system is used at least for removing a process residue from a treatment object, which process residue is formed on the treatment object, at least in part, as a result of removing an ion implanted photoresist from the treatment object. A plasma is generated within a chamber using a hydrocarbon gas in combination with oxygen gas in a way which subjects the process residue to the plasma for use in removal of the process residue. The plasma is free of halogens, at least to an approximation.

In another aspect of the present invention, a plasma reactor system is used at least for removing a process residue from a treatment object, which process residue is formed on the treatment object, at least in part, as a result of removing an ion implanted photoresist from the treatment object. A plasma, that is substantially halogen free, is generated in a treatment chamber using a hydrogen containing gas in combination with oxygen gas such that an overall gas mixture includes at least 15% hydrogen in a way which subjects the process residue to the plasma for use in removal of the process residue.

### BRIEF DESCRIPTIONS OF THE FIGURES

The present invention may be understood by reference to the following detailed description taken in conjunction with the drawings briefly described below.

FIG. 1 is a diagrammatic view, in elevation, of a treatment system for use in accordance with the present invention.

FIG. 2 is a flow diagram illustrating one implementation of a highly advantageous, overall method, performed in accordance with the present invention, for removing an ion implanted photoresist layer from a treatment object.

FIGS. 3 and 4 are diagrammatic views, in cross-sectional elevation, illustrating the formation of an implant crust when photoresist is exposed to ion implant species.

FIG. 5 is a diagrammatic view, in elevational cross-section showing removal of the ion implantation crust, in accordance with the present invention, in a way which leaves an underlying portion of photoresist that is not altered by ion implantation.

FIG. 6 is a diagrammatic view, in elevation, illustrating a residue which remains on the substrate and its removal in accordance with the present invention.

### DETAILED DESCRIPTION OF THE INVENTION

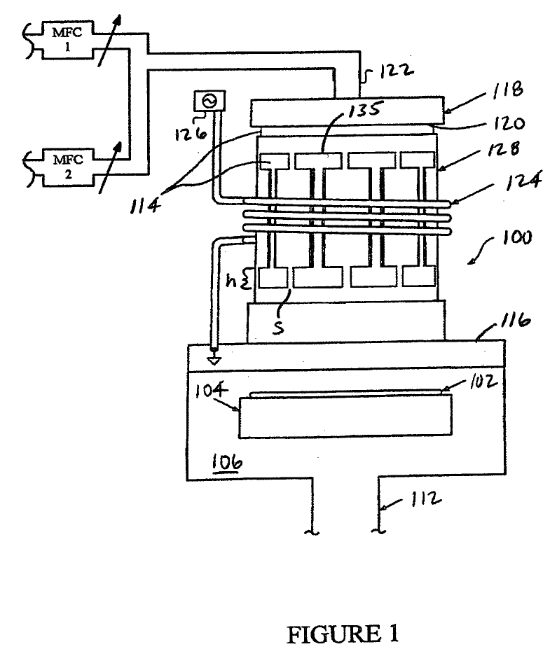

FIG. 1 illustrates an inductively coupled plasma reactor system 100 used in the exemplary embodiment of the present invention. A semiconductor wafer 102 to be processed is placed on a support 104 in a treatment chamber 106. Support 104 may be heated or cooled by a heating or cooling system (not shown) to heat or cool wafers for processing. Gases are exhausted from the system through exhaust outlet 112. Support 104 rests on a stand (not shown). Support 104 may be electrically isolated and selectively coupled to an RF bias to accelerate ions toward the wafer for enhanced processing. See, e.g., U.S. Pat. No. 5,534,231. It is noted that the figures are not to scale in order to enhance the reader's understanding. Further, like reference numbers are applied to like components wherever possible throughout the various figures.

A plasma generation chamber 114 is situated above treatment chamber 106. It is noted that more than one plasma source may readily be provided for a single chamber, which is not shown for illustrative convenience. A top plate 116 of processing chamber 106 provides a common ground for the components of the plasma generation chamber, and comprises a conductive material such as aluminum or the like. The walls of the plasma generation chamber are formed using a nonconductive material such as quartz or alumina and have a thickness of approximately 3 to 8 mm. The plasma generation chamber walls are fixed at their base to top plate 116 of the processing chamber. A top lid 118 of the plasma generation chamber can be aluminum or similar conductive material or can be the same material as the generation chamber walls. An o-ring seal 120 is compressed between top lid 118 and the plasma generation chamber walls to provide a vacuum seal. A gas inlet 122 is provided through top lid 118 to introduce gases into plasma generation chamber 114.

An inductor adjacent to the plasma generation chamber, such as induction coil 124, provides power into the plasma generation chamber. In the exemplary embodiment, induction coil 124 is a helical coil of copper tubing with approximately two to four turns encircling the plasma generation chamber. Other inductor configurations with a different size, number of turns or in a different shape, such as a conical or pancake shape, may also be used. Induction coil 124 is connected to a radio frequency (RF) source 126 through an impedance match network or transformer (not shown). Inductively-coupled RF power is typically supplied to the reactor at one of the Industry, Scientific, Medical (ISM) standard frequencies of 13.56, 27.12, 40.68 MHz, or other harmonics of the 13.56 MHz ISM standard frequency but any RF frequency from 1 to 100 MHz would also be usable. Usually, the power is supplied to the coils through an impedance matching network. RF energy is typically applied to the induction coil at a power of between about 500 to 5,000 Watts. While the present invention has been described in the context of its use in conjunction with an inductively coupled plasma reactor, it is to be understood that any suitable form of plasma reactor or generator may be employed, while remaining within the scope of the appended claims. Alternative forms of plasma reactors include, but are not limited to parallel plate reactors, ECR reactors and microwave reactors.

A split Faraday shield 128 is provided between induction coil 124 and plasma generation chamber 114. The bottom of split Faraday shield 128 sits on top plate 116 of the processing chamber. Compressed o-ring seals (not shown) are used to provide a vacuum seal between plasma generation chamber 114 and top plate 116 of the processing chamber.

Because shield 128 is grounded, it reduces capacitive coupling between the coil and the plasma. While capacitive coupling is reduced, there is still some capacitive coupling through slots 134 formed in the shield. The reduction in capacitive coupling, in turn, reduces the modulation of the plasma potential and the bombardment of the semiconductor wafer by charged particles. Neutral activated species continue to be produced and flow over the wafer surface. As described above, however, the invention may be implemented for acceleration of charged ions to bombard the wafer, but it must be remembered that a potentially damaging non-selective mechanical impact force is attendant thereto.

The number and size of the slots formed in the shield may be varied to change the level of capacitive coupling. In the exemplary embodiment, Faraday shield 128 defines slots which are narrow, typically about 1 cm wide or less, along the length of the shield having an overall “I” configuration wherein enlarged aperture end portions 135 of the slots are formed. These enlarged end portions have been included for purposes of enhancing magnetic field coupling from coil 124 to plasma in plasma chamber 114, while minimally increasing electric field coupling. In the exemplary embodiment, for use with 200 mm silicon wafers, the diameter of the Faraday Shield is about 200 mm with typically 8 slots or more equally spaced from one another. It is noted that the diameter of the source can be larger than 200 mm and would typically allow for a larger number of slots. Moreover, the the size of the source is generally designed to coincide with the substrate size (i.e., 300 mm wafers and larger next generation wafers and, for example, a flat panel display system would use a considerably larger plasma source Insofar as the removal of ion implanted photoresist crust, performed in accordance with the present invention and yet to be described, it is to be understood that any suitable Faraday shield may be used and, in fact, a Faraday shield is not a requirement. At the same time, however, it is to be understood that I-slot Faraday shield 128 is considered to be useful in any inductively plasma reactor system for purposes of enhancing magnetic field coupling without adverse introduction of electric field effects. Moreover, the use of rectangular end portions is not required and any suitable shape may be utilized so long as this intended result is achieved. In the present example, end aperture portions 135 are formed having a height, h, of approximately 35 mm and a separation thickness, s, between adjacent ones of the end aperture portions of approximately 12 mm.

Still referring to FIG. 1, gases are introduced through a pair of mass flow controls that are labeled MFC 1 and MFC 2 having shutoff valves associated therewith. In accordance with the present invention, MFC 1 is used to introduce oxygen, O₂, through showerhead 120 while MFC 2 is used to introduce a hydrocarbon gas such as, for example, methane, CH₄. Wafers carrying an implanted photoresist crust were subjected to dry plasma etching in system 100 using a methane and oxygen mixture. More specifically, remarkable results were empirically demonstrated using mixtures of 50% methane and 50% oxygen as well as 75% CH₄ with 25% O₂ and 75% O₂ with 25% CH₄. It is noted that such figures, throughout the present application, are given as percentage gas flow, since gases are typically delivered by measuring standard cubic centimeters per minute (sccm). Further process parameters include operating inductive coil 124 at a power of approximately 3,000 watts and providing pressure in treatment chamber 106 of approximately 3 torr. Although prior art processes typically operate at lower power and pressure values, increases in these values are not required. In this regard, it is considered that results attainable at prior art pressure and power values using the new process gas mixture provide sweeping advantages over prior art results. As will be described in further detail, the results achieved using the increased pressure and power values are no less than remarkable as compared to state of the art implanted photoresist crust removal techniques. Using these parameters, the implant crust on the test wafers was removed at 2 to 8 microns per min. Moreover, post treatment examination of the test wafers revealed that little or no residue remained. The present invention considers any hydrocarbon gas as useful which is capable of forming low molecular weight hydrocarbon radicals such as CH₂ and/or possibly CH₃ radicals. Any hydrocarbon gas that when introduced into the plasma is capable of generating low molecular weight radicals (radicals having a molecular weight less than approximately 30) is considered as being useful including, but not limited to methane (CH₄), propane (CH₃CH₂CH₃), ethane (C₂H₆ or CH₃CH₃), acetylene (C₂H₂ or HC═CH), allene or propadiene (C₃H4 or H₂C=C=CH₂), butadiene or methylallene (C₄H₆ or H₂C=C=CHCH₃), butane (C₄H₁₀ or CH₃CH₂CH₂CH₃), butene (C₄H₈ or CH₃CH₂CH=CH₂), cyclopropane (C₃H₈), dimethylamine ((CH₃)₂NH), dimethyl ether ((CH₃)₂O), dimethylpropane or isobutane (C₅H₁₂ or (CH₃)₂CHCH₃), ethane (C₂H₆ or CH₃CH₃), ethylacetylene (C4H6 or CH₃C═CCH₃), ethylene (C2H4 or H₂C=CH₂), propylene or propene (C₃H₆ or CH₃CH═CH₃), methanol (CH₃OH) or any deuterated form of a suitable hydrocarbon gas. Such hydrocarbon gas or deuterated form being in the range of 15% to 85% of the overall mixture.

It is important to understand that plasma formed using a hydrocarbon gas in combination with oxygen gas is not limited to removal of implant crust. That is, this plasma may be employed to remove not only the implant crust, but an underlying, unaltered portion of photoresist. Moreover, residues can be removed from the treatment object using this highly advantageous plasma. In this regard, residue removal, using this plasma, may be performed irrespective of different processes that might be employed to remove implant crust and unaltered photoresist. Additionally, this plasma can be used in a highly advantageous one-step process for removing the implant crust, underlying photoresist and residues from a treatment object. Further, it is recognized that removal of implant crust and bulk, underlying and unaltered photoresist may occur simultaneously. Such simultaneous removal may include mechanisms such as, for example, undercutting of the implant crust. Such a result may obtain since sidewalls of the photoresist that are generally parallel to the ion implantation direction will exhibit a thinner implant crust than photoresist surfaces that are generally normal to the ion implantation direction. Accordingly, the thinner sidewalls may be removed in a way which exposes the underlying photoresist to undercutting by the plasma. An appropriate plasma will produce a highly advantageous simultaneous removal of implant crust and underlying bulk photoresist. As a further advantage, removal of the photoresist layer and overlying implant crust has been demonstrated solely using downstream etching processes. That is, a reactive ion etching (RIE) step was not required, even in a highly advantageous single step process. This benefit is thought to be attributable to undercutting effects, as described above.

In one aspect of the present invention, hydrogen gas (H₂) is used as the hydrogen containing gas, as an alternative to a hydrocarbon gas. Referring to FIG. 1, the hydrogen can be introduced into the reaction vessel by MFC 2. Using hydrogen gas in combination with oxygen, similarly favorable results were achieved. One useful mixture was found to be 50% H₂ with 50% O₂. Moreover, this configuration was found to be extremely effective when used to remove implant crust at a pressure of 1 Torr when treating a 300 mm wafer, although a pressure range of approximately 0.5 to 4 Torr is considered as being useful with a hydrogen content of 15% to 85%. Once again, it is important to understand that plasma formed using hydrogen gas in combination with oxygen gas is not limited to removal of implant crust, but may be employed to remove (i) implant crust, (ii) an underlying, unaltered portion of photoresist and (iii) residues in a single step overall process. Further, it is recognized that removal of implant crust and bulk, underlying and unaltered photoresist may occur simultaneously using such a plasma produced from hydrogen and oxygen gases, as described above. Like the hydrocarbon/oxygen plasma, an appropriate hydrogen/oxygen plasma will produce a highly advantageous simultaneous removal of implant crust and underlying bulk photoresist which further enables a single step downstream processing environment. Moreover, like the hydrocarbon/oxygen plasma, a hydrogen/oxygen plasma can be directed to removal of ion implantation photoresist residues, irrespective of those prior process steps which left the residues in place on a treatment object.

The present invention desires to avoid the use of halogens (i.e., fluorine, chlorine, bromine and iodine) in the plasma. While the appended claims use the term “halogen free” for descriptive purposes, it is to be understood that this term is not intended to encompass naturally occurring instances of halogens, but rather that halogens are not deliberately introduced in the mixture for plasma generation purposes. Such a plasma may be considered as being halogen free at least to a practical approximation. As discussed above, Applicant is unaware of any effective plasma technique that is capable of removing implanted photoresist crust which does not rely on halogens or use of high energy ions. The present invention seeks to avoid the use of halogens for the reason that halogen radicals are not selective to the photoresist crust. In other words, halogen species will attack a treatment object such as, for example, a semiconductor wafer having oxides and/or circuit structure beneath the photoresist with any given opportunity to do so, thereby causing undesirable etching and/or damage. In this regard, it is submitted that there are certain teachings in the prior art which clearly render the use of a hydrocarbon gas and hydrogen gas [H₂], as taught herein, to be neither trivial nor obvious, as will be described immediately hereinafter.

Initially, it is important to understand that photoresist is itself a polymerized cross-linked hydrocarbon material which is inherently stable. In this regard, one of ordinary skill in the art avoids hydrocarbon containing plasma since one would assume that the added hydrocarbons would simply deposit further hydrocarbon material or further polymerize the implanted photoresist surface. Specifically, photoresist is formed of CH₂ chains. Methane, CH₄, transforms to CH₂ with the removal of two hydrogen atoms. One of ordinary skill in the art would expect this reaction to readily occur in a plasma, such that the produced CH₂ would then be deposited. For this reason alone, it is submitted that the prior art has avoided the use of hydrocarbons. There is, however, another reason for which the prior art is thought to have avoided hydrocarbon use, as will be described immediately hereinafter.

As will be remembered from discussions above, the prior art exhibits a reliance on halogen radicals for purposes of effective photoresist implant crust removal, as well as residue removal). An additional compelling reason that one of ordinary skill in the art would not use a hydrocarbon containing gas resides in the fact that when a hydrogen containing gas (including, of course, hydrogen gas itself) is supplied to the plasma, the hydrogen will immediately scavenge the halogen radicals from the plasma. For example, if chlorine is present, HCI is formed. The effect then is to produce an acid from any halogen that is present: HCI, HF, HBr and HI. This would tend to reduce the availability of the very halogen that is being added. While this result is tolerable at very low hydrogen concentrations such as seen in the prior art and may even contribute in some way to process effectiveness, it is submitted that anyone of ordinary skill in the art would assume that higher levels of hydrogen would effectively remove all of the halogens to the detriment of the dry etching process. This behavior, in combination with perceived polymerization effects, is thought to have prevented anyone from attempting to solve the implant crust removal problem, as has been solved by the present invention.

The remarkable effects demonstrated through the use of the present invention are theorized to avoid the aforedescribed polymerization problem for a particular reason. Specifically, it is thought that the relatively high percentage of oxygen combines with the CH₂ present in the plasma and at the surface of the photoresist so as to terminate the CH₂ chain building process. That is, there is a sufficient amount of oxygen present to interrupt any forming CH₂ chain with an oxygen atom. For instance, HCHO, is readily produced. This molecule comprises formaldehyde (or methanal) which is a stable, typically gaseous molecule in a plasma environment which, when produced, is pumped out as exhaust. Accordingly, the present invention recognizes and accepts that some of the introduced oxygen is consumed by the hydrocarbon gas.

Insofar as effectiveness of implant crust removal and residue removal, it is thought that the remarkable results achieved by the present invention are attributable, at least in part, to the generation of CH₂ and/or possibly CH₃ radicals.

It is important to understand that the present invention contemplates effective removal of photoresist implant crust using hydrogen in combination with oxygen at approximately 15% to 85% hydrogen in the overall mixture. Applicant is unaware of any prior art technique relying on such a hydrogen content. Effectiveness should be enhanced by inducing higher power into the plasma and the addition of other suitable hydrogen containing gases such as NH₃, N₂H₂, H₂S or their deuterated forms and at higher pressure, as described above, in order to increase hydrogen radicals action implant crust.

In view of the foregoing details, the present invention further recognizes a highly advantageous overall method for purposes of removing photoresist implant crust and residues, as will be further described immediately hereinafter.

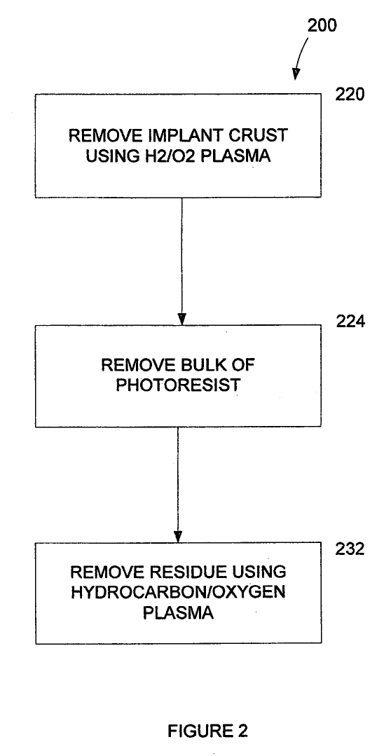

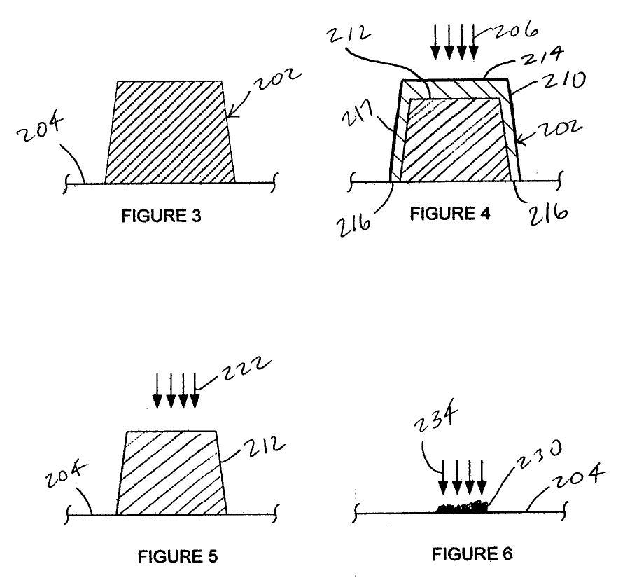

Attention is now directed to FIGS. 2-6, illustrating an overall method, generally indicated in FIG. 2 by the reference number 200, for removing photoresist implant crust in accordance with the present invention and using the system of FIG. 1. FIGS. 3 and 4 cooperatively illustrate the formation of such an implanted photoresist beginning with a photoresist stripe 202 formed on a substrate 204 (only partially shown). In FIG. 4, photoresist stripe 202 is exposed to ions 206, indicated using arrows, which form an implanted crust 210 surrounding an underlying, unaltered portion 212 of the original photoresist. The implanted dopants may comprise, but are not limited to Arsenic (As), along with Phosphorus (P) and Boron (B). The implantation process is often done at energies ranging from 5-500 KeV. The implantation dose, in the instance of high dose ion implants, can be greater than 1.0×10⁵ ions/cm².

Referring to FIG. 4, original resist layer 202 can be altered in at least three different ways (any one of or any combination of which may exist after ion implantation) as a result of ion implantation. First, a top layer 214 and, to a lesser degree, sidewalls 216 of the resist pattern may be embedded with the inorganic implant ion species (As, P, B). As the implant species penetrate the photoresist, they alter the polymer make-up of the photoresist, cross-linking the polymer chains of which the photoresist is made up. This cross-linking carbonizes and hardens top-layer 214 and sidewalls 216. Such carbonization of the resist can be designated as the second method of alteration of the resist. Further, the original resist layer can be altered in a third way: As the implanted species strike the areas of the substrate that are not covered by the resist (not shown), the species can sputter off atoms from the substrate (usually, substrate top film is Si or SiO₂). The sputtered atoms, will deposit onto sidewalls 214 and, to a lesser degree, the top of the resist. The latter two effects are illustrated by thickened edges 217 about the exterior periphery of the photoresist. Accordingly, photoresist crust 210 consists of any one of or any combination of these three effects.

Referring to FIGS. 2, 4 and 5, method 200 begins with step 220 in which implanted photoresist 202, along with crust 210, is exposed to a plasma 222 (indicated by arrows in FIG. 5) that is generated using hydrogen gas and oxygen gas. As described above, a 50% ratio of these two gases may be used or other suitable combination wherein hydrogen content is in a range of from approximately 15% to 85%, at a treatment pressure in a range from approximately 0.5 to 4.0 Torr, although an upper limit of up to approximately 15 Torr may be achieved. As described above, favorable results were empirically demonstrated at approximately 1 Torr. Following exposure to H₂ and O₂ plasma 222, underlying photoresist 212 should remain on substrate 204, as shown in FIG. 5. Although it is to be understood that some residue of the implant crust as well as other effects may form residues, as will be further described below.

Referring to FIG. 5, after having removed the implant crust in step 222, step 224 removes underlying photoresist 212, which remains on substrate 204. Any suitable process may be employed for this purpose. Examples of well known processes which are contemplated include, but are not limited to O₂ containing processes which may also include nitrogen and less than approximately 2% overall hydrogen.

Referring to FIG. 6, following step 224, a residue 230 may remain on substrate 204. It is noted that the amount of residue and relative proportions have been exaggerated for illustrative purposes and this figure, as is applicable to all of the figures, is not to scale. The residue can consist of remnants of: (1) sputtered silicon or silicon oxide (monoxide or dioxide or whatever material the substrate is formed from), (2) carbonized materials and (3) the implanted species. That is, residue 230 may contain any one or all of these materials. In this regard, the term “residue(s)” is considered to refer to all such forms remaining after ion implantation.

In step, 232 residue 230 is removed using a plasma 234 (indicated using arrows in FIG. 6) that is generated using a mixture of a hydrocarbon gas and oxygen gas. As described in detail above, methane gas may be used as the hydrocarbon gas, having a methane gas content in a range from approximately 15% to 85%. More specifically, mixtures of 50% methane and 50% oxygen as well as 75% CH₄ with 25% O₂ and 75% O₂ with 25% CH₄ have been demonstrated as being effective. A treatment pressure in a range from approximately 0.5 to 4.0 Torr may be used, although an upper limit of up to approximately 15 Torr is acceptable. As specific examples, pressures of 1 Torr and 3 Torr have been found to be useful. It is considered that this overall method including step 232 is highly advantageous, since the plasma is selective to the photoresist and residue, thereby leaving underlying structures unaltered.

Still referring to FIG. 6, in one highly advantageous alternative embodiment, step 222 may be used in sequence with step 232, without step 224. That is, step 222, using a hydrogen/oxygen plasma may be employed primarily for purposes of removing the implant crust. Thereafter, step 232, using a hydrocarbon/oxygen plasma, may be employed primarily for purposes of removing the bulk photoresist and implant residues. Of course, in the instance of using either plasma, simultaneous removal of implant crust and bulk photoresist may readily occur, as described above.

Referring to FIGS. 1 and 2, it should be appreciated that a manifold arrangement (not shown) may be provided upstream of MFC 1 for purposes of selecting either hydrogen gas or a hydrocarbon gas to flow thereto. Such an arrangement may readily be implemented by one having ordinary skill in the art in possession of this overall disclosure.

Having described the present invention in detail above, it is appropriate to now draw a number of comparisons with the prior art, which was addressed briefly above. Again, the '424 and '871 patents share an overriding concern with exposing an implant crust to oxygen containing plasma, since it is assumed that nonvolatile oxide residues of the ion implant species will form and that such residues are, at best, very difficult to remove. The present invention, in contrast, has completely swept aside this assumption by using oxygen in combination with either hydrogen or hydrocarbon gases for plasma formation while providing remarkable process results. Upon process completion, the presence of nonvolatile oxide residue has been empirically demonstrated as insignificant when the present invention is practiced consistent with this overall disclosure. While the exact mechanism which produces this highly advantageous result is being investigated in further detail, it is proposed that whatever amount of nonvolatile oxide residue is formed from the implant crust is simultaneously removed for practical purposes. Irrespective of the mechanism at play, it is submitted that the present invention represents a new paradigm in the field of photoresist removal, particularly in the instance of ion implanted crust.

As another comparison with the prior art, it is important to understand that hydrogen containing plasma, which is devoid of oxygen, produces slow etch rates. It is proposed that the '424 and '871 patents teach a two step removal process wherein oxygen is used in the second step in order to achieve a reasonable overall etch rate. In contrast, the oxygen containing plasmas of the present invention have been found to produce better that acceptable etch rates even in a single step process. That is, either a hydrocarbon/oxygen plasma or a hydrogen/oxygen plasma effectively removes the implant crust, underlying bulk photoresist and residue in one step.

Although each of the aforedescribed physical embodiments have been illustrated with various components having particular respective orientations, it should be understood that the present invention may take on a variety of specific configurations with the various components being located in a wide variety of positions and mutual orientations. Furthermore, the methods described herein may be modified in an unlimited number of ways, for example, by reordering, modifying and recombining the various steps. Accordingly, it should be apparent that the arrangements and associated methods disclosed herein may be provided in a variety of different configurations and modified in an unlimited number of different ways, and that the present invention may be embodied in many other specific forms without departing from the spirit or scope of the invention. Therefore, the present examples and methods are to be considered as illustrative and not restrictive, and the invention is not to be limited to the details given herein, but may be modified at least within the scope of the appended claims.

What is claimed is:

1. A plasma reactor system at least for use in removing a process material crust from a treatment object, said system comprising:
a treatment chamber within which a plasma is generated using a hydrocarbon gas in combination with oxygen gas in a way which subjects the process material crust to the plasma for use in removal of the process material crust, said plasma being free of halogens, at least to an approximation.

2. The system of claim 1 wherein said hydrocarbon gas produces low molecular weight radicals in said plasma.

3. The system of claim 2 wherein said low molecular weight radicals include a molecular weight of less than approximately 30.

4. The system of claim 2 wherein said radicals include at least one of CH₂ radicals and CH₃ radicals in the plasma.

5. The system of claim 1 wherein said process material is a photoresist and said process material crust is formed by ion implantation of an original photoresist layer on a surface of said treatment object.

6. The system of claim 5 wherein said process material crust overlies an unaltered region of said original photoresist layer and said plasma formed using said hydrocarbon gas in combination with oxygen is used to remove said unaltered region of photoresist.

7. The system of claim 6 wherein said process material crust and said unaltered region of said original photoresist layer are simultaneously removed using said plasma formed with said hydrocarbon gas in combination with oxygen gas.

8. The system of claim 7 wherein said plasma is generated with downstream plasma generation means.

9. The system of claim 1 wherein the treatment object is a semiconductor wafer.

10. The system of claim 1 wherein said hydrocarbon gas is in a range of from approximately 15% to 85% of an overall mixture with the oxygen gas.

11. The system of claim 1 wherein said hydrocarbon gas is methane.

12. The system of claim 1 wherein 75% methane and 25% oxygen form an overall gas mixture.

13. The system of claim 1 including an inductive coil for inducing power into the plasma at a power level of at least 200 W.

14. The system of claim 1 including an inductive coil for inducing power into the plasma at a power level of approximately 3000 watts.

15. The system of claim 1 including a parallel plate reactor for generating said plasma.

16. The system of claim 1 including a microwave plasma source for generating said plasma.

17. The system of claim 1 wherein said treatment chamber is at a pressure selected in the range of approximately 0.5 to 15 Torr.

18. The system of claim 1 wherein said treatment chamber is at a pressure of approximately 3 Torr.

19. The system of claim 1 wherein said chamber is at a pressure of approximately 1 Torr.

20. In a plasma reactor system at least for use in removing a process material crust from a treatment object, a method comprising the steps of:
generating a plasma in a plasma chamber using a hydrocarbon gas in combination with oxygen gas such that the plasma is halogen free, at least to an approximation, in a way which subjects the process material crust to the plasma for use in removal of the process material crust.

21. The method of claim 20 wherein said hydrocarbon gas produces low molecular weight radicals in said plasma.

22. The method of claim 21 wherein said low molecular weight radicals include a molecular weight of less than approximately 30.

23. The method of claim 21 wherein said hydrocarbon gas is capable of generating at least one of CH₂ radicals and CH₃ radicals in the plasma.

24. The method of claim 20 wherein said process material is a photoresist and said process material crust is formed by ion implantation of an original photoresist layer on a surface of said treatment object and said plasma is generated so as to contact the process material.

25. The method of claim 24 wherein said process material crust overlies an unaltered region of said original photoresist layer and the method includes using said plasma to remove said unaltered region of photoresist.

26. The method of claim 25 including simultaneously removing said process material crust and said unaltered region of said original photoresist layer using said plasma.

27. The method of claim 26 including downstream generation of said plasma.

28. The method of claim 20 wherein the treatment object is a semiconductor wafer.

29. The method of claim 20 wherein said hydrocarbon gas is in a range of from approximately 15% to 85% of an overall mixture with the oxygen gas.

30. The method of claim 20 wherein said hydrocarbon gas is methane.

31. The method of claim 20 wherein 75% methane and 25% oxygen form an overall gas mixture.

32. The method of claim 20 including the step of inducing power into the plasma at a power level of at least 500 watts.

33. The method of claim 20 the step of including inducing power into the plasma at a power level in a range from approximately 500 to 5000 watts.

34. The method of claim 20 including the step of pressurizing the said treatement chamber at a pressure selected in the range of approximately 0.5 to 15 torr.

35. The method of claim 20 including the step of pressurizing the said treatment chamber at a pressure of approximately 3 torr.

36. The method of claim 20 including the step of pressurizing the said treatment chamber at a pressure of approximately 1 torr.

37. A plasma reactor system at least for use in removing a process material crust from a treatment object, said system comprising:
a treatment chamber within which a plasma is generated, that is substantially halogen free, using a hydrogen containing gas in combination with oxygen gas such that an overall gas mixture includes at least 15% hydrogen in a way which subjects the process material crust to the plasma for use in removal of the process material crust.

38. The system of claim 37 wherein said hydrogen containing gas consists essentially of hydrogen gas.

39. The system of claim 38 wherein each of said hydrogen gas and said oxygen gas make up approximately one-half of the overall gas mixture.

40. The system of claim 38 wherein said hydrogen gas is provided in the overall gas mixture in a range from approximately 15% to 85%.

41. The system of claim 38 including pressurizing the treatment chamber at a pressure selected in the range of approximately 0.5 to 15 Torr.

42. The system of claim 37 wherein said process material is a photoresist and said process material crust is formed by ion implantation of an original photoresist layer on a surface of said treatment object.

43. The system of claim 42 wherein said process material crust overlies an unaltered region of said original photoresist layer and said plasma formed using said hydrogen gas in combination with oxygen is used to remove said unaltered region of photoresist.

44. The system of claim 43 wherein said process material crust and said unaltered region of said original photoresist layer are simultaneously removed using said plasma formed with said hydrogen gas in combination with oxygen gas.

45. The system of claim 37 wherein the treatment object is a semiconductor wafer.

46. The system of claim 37 wherein said hydrogen containing gas is in a range of from approximately 15% to 85% of an overall mixture with the oxygen gas.

47. The system of claim 37 including an inductive coil for inducing power into the plasma at a power level of at least 500 Watts.

48. The system of claim 37 including an inductive coil for inducing power into the plasma at a power level in a range from approximately 500 to 5000 watts.

49. The system of claim 37 including a parallel plate reactor for generating said plasma.

50. The system of claim 37 including a microwave plasma source for generating said plasma.

51. The system of claim 37 wherein said treatment chamber is at a pressure selected in the range of approximately 0.5 to 15 Torr.

52. The system of claim 37 wherein said treatment chamber is at a pressure of approximately 3 Torr.

53. The system of claim 37 wherein said treatment chamber is at a pressure of approximately 1 Torr.

54. In a plasma reactor system at least for use in removing a process material crust from a treatment object, a method comprising the steps of:
generating a plasma in a plasma chamber using a hydrogen containing gas in combination with oxygen gas such that the plasma is substantially halogen free and so that an overall gas mixture includes at least 15% hydrogen in a way which subjects the process material to the plasma for use in removal of the process material crust.

55. The method of claim 54 wherein said hydrogen containing gas consists essentially of hydrogen gas.

56. The method of claim 55 wherein each of said hydrogen gas and said oxygen gas make up at least approximately one-half of the overall gas mixture.

57. The method of claim 56 wherein said hydrogen gas is provided in the overall gas mixture in a range from approximately 15% to 85%.

58. The method of claim 55 including pressurizing the treatment chamber at a pressure selected in the range of approximately 0.5 to 15 Torr.

59. The method of claim 54 wherein said process material is a photoresist and said process material crust is formed by ion implantation of an original photoresist layer on a surface of said treatment object.

60. The method of claim 54 wherein the treatment object is a semiconductor wafer.

61. The method of claim 54 wherein said hydrogen is in a range of from approximately 15% to 85% of an overall mixture with the oxygen gas.

62. The method of claim 54 including the step of inducing power into the plasma at a power level of at least 500 Watts.

63. The method of claim 54 the step of including inducing power into the plasma at a power level in a range from approximately 500 to 5000 watts.

64. The method of claim 54 including the step of pressurizing the said treatment chamber at a pressure selected in the range of approximately 0.5 to 15 Torr.

65. The method of claim 54 including the step of pressurizing the treatment chamber at a pressure of approximately 3 Torr.

66. The method of claim 54 including the step of pressurizing the treatment chamber at a pressure of approximately 1 Torr.

67. A plasma reactor system at least for use in removing a process material crust from a treatment object, said system comprising:
a treatment chamber within which a halogen free plasma is generated using a gas in combination with oxygen gas in a way which produces at least one of CH₂ radicals and CH₃ radicals in said plasma to subject the process material crust to the plasma for use in removal of the process material crust.

68. In a plasma reactor system at least for use in removing a process material crust from a treatment object, a method comprising the steps of:
generating a halogen free plasma in a plasma chamber using a gas in combination with oxygen gas in a way which produces at least one of CH₂ radicals and CH₃ radicals in the plasma and which subjects the process material to the plasma for use in removal of the process material crust.

69. A plasma reactor system at least for use in removing a photoresist layer from a treatment object, said photoresist layer including an outermost crust formed by exposure of the photoresist to an ion implantation source, said system comprising:
a treatment chamber within which said treatment object is supported;
first means for introducing a first halogen free plasma in said treatment chamber using hydrogen gas in combination with oxygen gas in a way which subjects the outermost crust to the first plasma to remove at least a substantial portion of the outermost crust so as to leave an innermost portion of said photoresist layer on the treatment object;
second means for use in removing at least a substantial part of said innermost portion of said photoresist layer such that a residue remains on the treatment object, said residue relating to at least one of the outermost crust and the innermost portion of the photoresist layer; and
third means for generating a second halogen free plasma using a hydrocarbon gas in combination with oxygen gas and for exposing the residue to the second plasma to remove said residue from said treatment object.

70. In a plasma reactor system at least for use in removing a photoresist layer from a treatment object, said photoresist layer including an outermost crust formed by exposure of the photoresist to an ion implantation source, a method comprising:
supporting said treatment object within a treatment chamber;
producing a first halogen free plasma using hydrogen gas in combination with oxygen gas and subjecting the outermost crust of the treatment object in said treatment chamber to the first plasma to remove at least a substantial portion of the outermost crust so as to leave an innermost portion of said photoresist layer on the treatment object;
removing at least a substantial part of said innermost layer of said photoresist layer such that a residue remains on the treatment object, said residue relating to at least one of the outermost crust and the innermost portion of the photoresist layer; and
generating a second halogen free plasma using a hydrocarbon gas in combination with oxygen gas and exposing the residue to the second plasma to remove said residue from said treatment object.

71. A plasma reactor system at least for use in removing a photoresist layer from a treatment object, said photoresist layer including an outermost crust formed by exposure of the photoresist to an ion implantation source in a way which may additionally form implant residues, said system comprising:
a treatment chamber within which said treatment object is supported;
first means for introducing a first plasma in said treatment chamber using hydrogen gas in combination with oxygen gas such that the first plasma is substantially free of halogens and in a way which subjects at least the outermost crust to the first plasma to remove at least a portion of the outermost crust so as to leave an underlying portion of said photoresist layer on the treatment object along with at least a portion of said implant residues; and
second means for generating a second plasma using a hydrocarbon gas in combination with oxygen gas such that the second plasma is substantially free of halogens and for exposing the underlying portion of the photoresist layer and any remaining portion of the implant residues to the second plasma for removal from said treatment object.

72. The system of claim 71 wherein said first means removes a substantial part of said outermost crust such that said underlying portion of the photoresist corresponds to an unaltered photoresist region previously disposed beneath the outermost crust and said second means removes a substantial part of said underlying portion of the photoresist.

73. In a plasma reactor system at least for use in removing a photoresist layer from a treatment object, said photoresist layer including an outermost crust formed by exposure of the photoresist to an ion implantation source in a way which may additionally form implant residues, a method comprising:
supporting the treatment object in a treatment chamber;
introducing a first plasma in said treatment chamber formed using hydrogen gas in combination with oxygen gas such that the first plasma is substantially free of halogens and in a way which subjects at least the outermost crust to the first plasma to remove at least a portion of the outermost crust so as to leave an underlying portion of said photoresist layer on the treatment object along with at least a portion of said implant residues; and
generating a second plasma using a hydrocarbon gas in combination with oxygen gas such that the second plasma is substantially free of halogens and exposing the underlying portion of the photoresist layer and any remaining portion of said implant residues to the second plasma for removing the innermost portion of the photoresist layer and the remaining implant residues from said treatment object.

74. The method of claim 71 wherein said first means removes at least a substantial part of said outermost crust such that said underlying portion of the photoresist corresponds to an unaltered photoresist region previously disposed beneath the outermost crust and said second means removes a substantial part of said underlying portion of the photoresist.

75. A plasma reactor system at least for use in removing a process residue from a treatment object, which process residue is formed on the treatment object, at least in part, as a result of removing an ion implanted photoresist from the treatment object, said system comprising:
a treatment chamber within which a plasma is generated using a hydrocarbon gas in combination with oxygen gas in a way which subjects the process residue to the plasma for use in removal of the process residue, said plasma being free of halogens, at least to an approximation.

76. In a plasma reactor system at least for use in removing a process residue from a treatment object, which process residue is formed on the treatment object, at least in part, as a result of removing an ion implanted photoresist from the treatment object, a method comprising:
generating a plasma in a plasma chamber using a hydrocarbon gas in combination with oxygen gas such that the plasma is halogen free, at least to an approximation, in a way which subjects the process residue to the plasma for use in removal of the process residue.

77. A plasma reactor system at least for use in removing a process residue from a treatment object, which process residue is formed on the treatment object, at least in part, as a result of removing an ion implanted photoresist from the treatment object, said system comprising:
a treatment chamber within which a plasma is generated, that is substantially halogen free, using a hydrogen containing gas in combination with oxygen gas such that an overall gas mixture includes at least 15% hydrogen in a way which subjects the process residue to the plasma for use in removal of the process residue.

78. The system of claim 77 wherein said hydrogen containing gas consists essentially of hydrogen gas.

79. In a plasma reactor system at least for use in removing a process residue from a treatment object, which process residue is formed on the treatment object, at least in part, as a result of removing an ion implanted photoresist from the treatment object, a method comprising:
generating a plasma in a plasma chamber using a hydrogen containing gas in combination with oxygen gas such that the plasma is substantially halogen free and so that an overall gas mixture includes at least 15% hydrogen in a way which subjects the process residue to the plasma for use in removal of the process residue.

80. The system of claim 77 wherein said hydrogen containing gas consists essentially of hydrogen gas.
